(19) United States
(12) Patent Application Publication
(10) Pub. No.: US 2025/0303580 A1
(43) Pub. Date: Oct. 2, 2025

(54) END EFFECTOR VISION WITH LASER ASSIST

(71) Applicants: KABUSHIKI KAISHA YASKAWA DENKI, Kitakyushu-shi (JP); Yasakawa America, Inc., Waukegan, IL (US)

(72) Inventor: John Charles ROGERS, Danville, CA (US)

(73) Assignees: KABUSHIKI KAISHA YASKAWA DENKI, Kitakyushu-shi (JP); Yaskawa America, Inc., Waukegan, IL (US)

(21) Appl. No.: 19/091,962

(22) Filed: Mar. 27, 2025

Related U.S. Application Data
(60) Provisional application No. 63/572,954, filed on Apr. 2, 2024.

(51) Int. Cl. B25J 11/00; B25J 9/16; B25J 13/08; G01B 11/06; G06T 7/521; H01L 21/68; H01L 21/687

(52) U.S. Cl. CPC B25J 11/0095; B25J 9/1653; B25J 13/089; G01B 11/0608; G06T 7/521; H01L 21/681; H01L 21/68707; G06T 2207/30148

(57) ABSTRACT

A robot including a robot arm having an end effector and a first laser diode provided on the end effector. The first laser diode is configured to emit a first laser light in a first direction. The robot further includes a camera configured to sense or detect first reflected light from an object upon which the first laser light contacts, and a processor configured to determine a clearance height between the end effector and the object using information from the first reflected light.

### CROSS-REFERENCE TO RELATED APPLICATION

The present application claims priority to U.S. Provisional Application No. 63/572,954, filed on Apr. 2, 2024, the entire contents of which are herein incorporated by reference.

### BACKGROUND OF THE INVENTION

### Field of the Invention

The present invention relates to an end effector for use for transporting objects such as a semiconductor wafer and methods of using such an end effector.

### Discussion of the Background

Heterogeneous integration and warped wafers are becoming more common within semiconductor chip manufacturing. Given pre-existing standards for cassette pitch and physical limitations on minimum blade thickness, it has become increasingly more difficult to handle warped (e.g., taco shaped warpage, bowl shaped warpage, etc.) or thicker wafers given the uncertainty of the magnitude of their warpage. Of particular concern is the ability to either extend or retract the robot end effector between two wafers without collision or drag out.

### SUMMARY OF THE INVENTION

The present disclosure advantageously provides a robot end effector including: a first laser diode configured to emit a first laser light in a first direction; a camera configured to sense or detect first reflected light from an object upon which the first laser light contacts; and a processor configured to determine a clearance height between the end effector and the object using information from the first reflected light.

The present disclosure also advantageously provides a robot including a robot arm having such robot end effector, where the first laser diode is provided on the robot end effector.

The present disclosure further advantageously provides a method including: providing a first laser diode and a camera on an end effector; using the first laser diode to emit a first laser light in a first direction; using the camera to sense or detect first reflected light from an object upon which the first laser light contacts; and using a processor to determine a clearance height between the end effector and the object using information from the first reflected light.

The present disclosure additionally advantageously provides a method including: providing a first laser diode and a camera on an end effector; using the first laser diode to emit a first laser light in a first direction; using the camera to sense or detect first reflected light from an object upon which the first laser light contacts; and using a processor to determine an amplitude of vibration of the end effector in a direction extending between the end effector and the object using information from the first reflected light over a period of time.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is a diagram illustrating a robot and a control unit;

FIG. 2 is a block diagram illustrating a control unit and drive units;

FIG. 3 is plan view of a workspace and a handling sequence;

FIGS. 4A-4C are plan views of arms employed with a robot;

FIG. 5 is a side view of a portion of an end effector extending and retracting between two wafers;

FIG. 6 is a top (plan) view of an embodiment of an end effector having a base portion, a wrist portion, and a blade portion;

FIG. 7 is a side view of a portion of an embodiment of an end effector approaching a wafer;

FIG. 8 is a schematic perspective view of an embodiment of an end effector approaching a warped wafer;

FIG. 9 is a graphical representation of a view the warped wafer in an x-y-z coordinate system;

FIG. 10 is a top schematic view of a laser and camera arrangement of an embodiment of an end effector;

FIG. 11 is a side schematic view showing a field of view of a camera in the laser and camera arrangement of FIG. 10;

FIG. 12 is an enlarged version of FIG. 11 with additional explanatory details;

FIG. 13 graphically shows a warped wafer and pad produced from a simulation of a camera image of a blade and a laser beam striking the warped wafer;

FIG. 14 schematically shows various types of reflection that can occur off a wafer and/or wall during a sensing operation;

FIGS. 15A-15D are images that show experimental examples of primary, secondary, and tertiary diffuse reflection of laser light on a silicon wafer;

FIGS. 16A-16C depict diagrams of parallel lasers and single camera arrangement with a wafer that is parallel to the lasers, where FIG. 16A depicts a front perspective view of a diagram of such an arrangement as would appear in a camera image, FIG. 16B depicts a side view of a diagram of such an arrangement, and FIG. 16C depicts a top view of a diagram of such an arrangement;

FIG. 17A depicts an enlarged version of FIG. 16A with additional explanatory details, and FIG. 17B shows a modified, partial version of FIG. 16B with an alternative height clearance result;

FIGS. 18A-18C depict diagrams of parallel lasers and single camera arrangement with a wafer that is not parallel to the lasers, where FIG. 18A depicts a front perspective view of a diagram of such an arrangement as would appear in a camera image, FIG. 18B depicts a side view of a diagram of such an arrangement, and FIG. 18C depicts a top view of a diagram of such an arrangement;

FIG. 19 depicts geometric relationships in an arrangement with one camera and one laser;

FIG. 20 depicts geometric relationships in an arrangement with one camera and one laser as observed in an x-y plane;

FIG. 21 shows a side view of an end effector having a leveling device for laser alignment;

FIG. 22 shows a camera image coordinate frame used during leveling (calibrating) of the laser(s) of the end effector and/or of a camera of the end effector of FIG. 21;

FIG. 23 shows a side view of an end effector being used to determine presence or absence of a wafer on a blade of the end effector;

FIG. 24 shows a side view of an end effector being used to sense a vertical position of a wafer or a series of vertically positioned wafers;

FIG. 25 shows a schematic view of features of a laser including a laser diode and a lens;

FIG. 26 shows a schematic view of a camera and features associated therewith;

FIG. 27 shows schematic views of a camera and features being viewed by the camera;

FIG. 28 depicts an embodiment of an end effector showing an alternative laser arrangement and an alternative camera arrangement;

FIG. 29 shows an enlarged view of a line in a bottom left portion of FIG. 15D;

FIG. 30 depicts geometric relationships used in modelling a laser beam having individual rays;

FIG. 31 depicts geometric relationships used in modelling the laser beam in coordination with a camera origin;

FIG. 32 depicts geometric relationships used to coordinate a camera origin, a beam origin, and an object element;

FIG. 33 depicts geometric relationships used to coordinate a camera origin/focal point, an inertia coordinate frame, an object element, and a camera array; and

FIG. 34 depicts an image processing simulation of a beam of laser light as seen by a camera array.

### DETAILED DESCRIPTION OF EXEMPLARY EMBODIMENTS OF THE INVENTION

Embodiments of the present invention will be described hereinafter with reference to the accompanying drawings. In the following description, the constituent elements having substantially the same function and arrangement are denoted by the same reference numerals, and repetitive descriptions will be made only when necessary.

Blade robots can be used to move wafers to and from a processing stage of a processing chamber or FOUP (Front Open Unified Pod) or other location at which a wafer is placed and retrieved. U.S. application Ser. No. 15/644,828, which issued as U.S. Pat. No. 10,580,681 discloses a robotic apparatus and method for transport of a workpiece that provides background teaching of an apparatus and method that the present invention can be utilized in conjunction with.

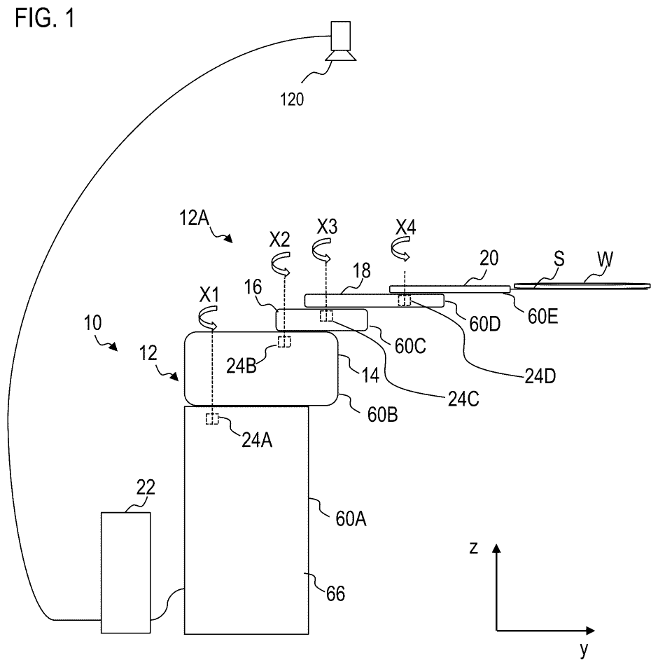

A configuration of a robotic apparatus 10 will be described according to an exemplary embodiment. FIG. 1 is an exemplary robotic apparatus 10 that includes a transfer robot (or robot) 12 and a robot controller (or control unit) 22. The robot 12 has an arm 12A that includes a plurality of arm members that are rotatable with respect to each other. The arm 12A includes torso 14 (fourth arm member), first arm 16 (third arm member), second arm 18 (first arm member), and third arm 20 (second arm member) as exemplary arm members, each of which is rotated by a respective drive unit 24A-24D (collectively referenced as drive units) provided therein or in association therewith. As illustrated in FIG. 1, the torso 14 is rotatable about pivot axis X1, the first arm 16 is rotatable about pivot axis X2, the second arm 18 is rotatable about pivot axis X3, and the third arm is rotatable about pivot axis X4, such that each arm unit rotates about a respective pivot axis (collectively referenced as pivot axes). The third arm 20 is connected to a distal end of the second arm 18 and includes a surface S that supports a substrate W, such as a semiconductor wafer. Substrate W is an example of a workpiece. Workpieces other than semiconductor wafers can be transported in the manner discussed below with reference to substrate W. The second arm 18 is connected to a distal end of first arm 16. The first arm 16 is connected to a distal end of torso 14, which is in turn connected to base 66. Therefore, base 66 supports torso 14, first arm 16, second arm 18, and third arm 20. The base 66 includes a housing 60A, the torso 14 includes a housing 60B, the first arm 16 includes a housing 60C, the second arm 18 includes a housing 60D, and the third arm, 20 includes a housing 60E (collectively referenced as housing). Robot 12 can be formed as a Selective Compliance Assembly robot (SCARA robot), for example.

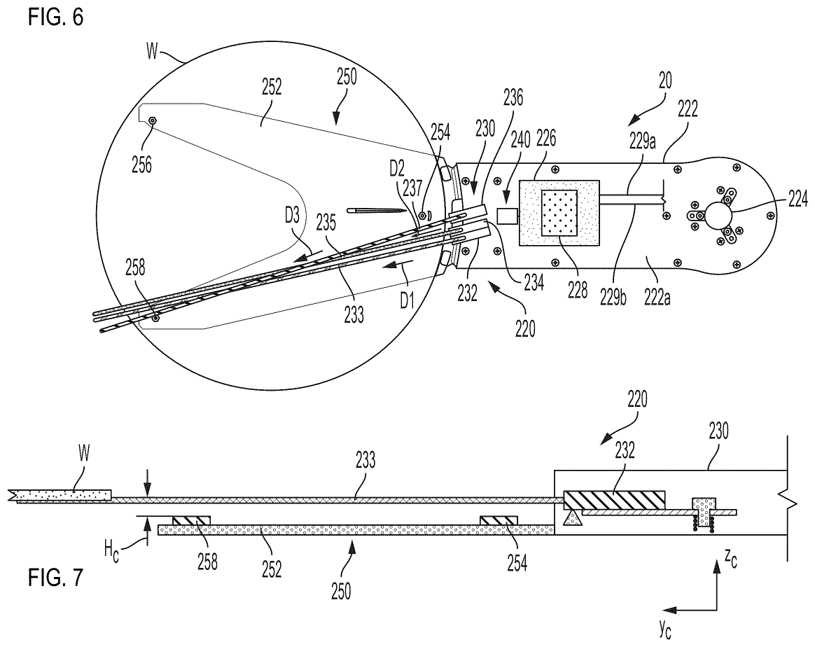

The third arm 20 can be provided as the end effector, for example, as shown in FIG. 6 and described below, with the lasers (e.g., laser diodes) and camera(s) provided thereon.

Control unit 22 outputs commands to bring each of the torso 14, first arm 16, second arm 18, and third arm 20 into motion, as will be described in further detail below. Control unit 22 can be included outside the housing of robot 12 as depicted in FIG. 1, or inside the housing of robot 12. Control unit 22 communicates with robot 12 and the drive units directly, or in conjunction with an intermediate control device, which can include an amplifier. When an amplifier is included as an intermediate device, control unit 22 is configured to issue commands to the amplifier, which in turns generates control signals for one or more of the drive units. Control unit 22 can also receive instructions from a higher-level device such as a programmable logic controller, for example.

As illustrated in FIG. 1, the torso 14 is rotatable about pivot axis X1, the first arm 16 is rotatable about pivot axis X2, the second arm 18 is rotatable about pivot axis X3, and the third arm 20 is rotatable about pivot axis X4. This rotational motion is accomplished by a corresponding drive unit constituted by a motor drive or servo motor, for example. Control unit 22 is configured to control the drive units for each of the torso 14, first arm 16, second arm 18, and third arm 20. Each drive unit provides feedback that indicates at least a position of the drive unit to control unit 22. The position feedback is provided directly from the respective drive units, which perform torque-sensing, from an external sensor 120, or any combination of torque-sensing drive units and external sensors. External sensor 120 can include some components. Control unit 22 controls the operation of drive units in accordance with the feedback information to control the position of each of the torso 14, the first arm 16, the second arm 18, and the third arm 20.

When the drive units are direct drive units, the drive units can be disposed within respective housings 60A-60D. For example, the drive unit 24A for the torso 14 can be provided in a housing 60A of base 66. Thus, separate drive unit housings for housing the motor and gears are not necessary when direct drive units are used for drive units.

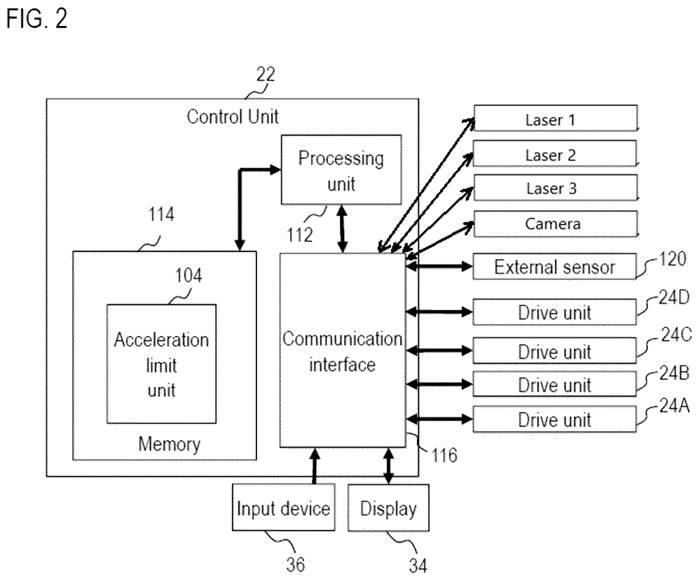

FIG. 2 illustrates an exemplary configuration of the control unit 22. As illustrated in FIG. 2, the drive units are each in communication with control unit 22. Although four drive units 24A-24D are depicted in FIG. 2, additional drive units can be provided for each respective axis, including torso 14, first arm 16, second arm 18, and third arm 20. Control unit 22 includes a processing unit 112 and a memory 114. Processing unit (processor) 112 is a processing device such as a microprocessor or CPU and communicates with memory 114 and executes instructions (e.g., software programs) provided by acceleration limit unit 104, which is stored in memory 114, which is a long-term non-volatile storage device such as a hard disk, solid state storage device, EEPROM, or other non-transitory storage medium. Acceleration limit unit 104 allows control unit 22 to command the drive units based on an allowable acceleration (acceleration limit) applied when robot 12 is brought into motion in order to transport substrate W. This allowable acceleration can be provided as an allowable acceleration value which is a predefined value determined in advance or set by a user, as described below. As the acceleration of substrate W is equivalent to the acceleration of surface S and third arm 20, the allowable acceleration is a maximum acceptable acceleration that can be applied to third arm 20, surface S, and substrate W. The allowable acceleration can be provided as a maximum acceptable value of jerk. Jerk is the time derivative of acceleration, or a rate of change of acceleration in time. The magnitude of jerk relates directly to the impulse to the substrate W. Higher impulse can lead to higher acceleration overshoot and thus higher peak acceleration. Thus, by limiting jerk, it is possible to ensure accurate tracking of a motion profile. As provided herein, the allowable acceleration and acceleration limit encompass the use of an allowable acceleration value, an allowable jerk value, or both.

Control unit 22 is in communication with the various lasers, such as Laser 1 (e.g., the green laser 234 in FIG. 6), Laser 2 (e.g., the blue laser 236 in FIG. 6), and Laser 3 (e.g., the red laser 232 in FIG. 6), and with the camera(s) (e.g., camera 240 in FIG. 6) provided on the end effector 20. The control unit 22 can directly communicate with the lasers and camera(s), or the control unit 22 can communicate with the lasers and camera(s) via the printed circuit board (PCB) (e.g., PCB 226 in FIG. 6), which is in communication with the lasers and camera(s). The control unit 22 can directly control the lasers/camera(s), or the PCB can directly control the lasers/camera(s), or both the control unit 22 and the PCB can control the lasers/camera(s) in conjunction with one another.

Control unit 22 is in communication with a user interface that includes an input device 34 and a display 36 that can include a visual display and audio input/output capabilities. Control unit 22 includes a wired and/or wireless communication interface 116 to communicate with input device 34 and display 36, and can also include a volatile memory. Communication interface 116 accepts input from input device 36, which can include a mouse and/or keyboard, and controls display 34 to display information to a user. Communication interface 116 can also receive feedback from each of the drive units and output commands to the respective drive units. If an external sensor 120 is used to provide position feedback, this feedback information is also received by communication interface 116. The issuance of commands to the drive units and the receipt of feedback can be accomplished by direct communication or through an intermediate device such as an amplifier.

A user can interact with input device 36 to configure the allowable acceleration set by acceleration limit unit 104. Thus, a user can observe the allowable acceleration with display 34 and set and/or modify the allowable acceleration with input device 36. Input device 36 and display 34 can be components of control unit 22 or provided as parts of a separate personal computer that communicates with communication interface 116.

Communication interface 116 of control unit 22 can be configured to receive data from display 34, input device 36, and the drive units. Alternatively, a separate communication interface 116 can be provided for the drive units alone. In this case, communication interface 116 for the drive units receives feedback from the drive units, via a cable, for example, and provides this feedback to processing unit 112. The communication interface 116 for the drive units outputs commands to control the drive units directly or through an intermediate device such as an amplifier.

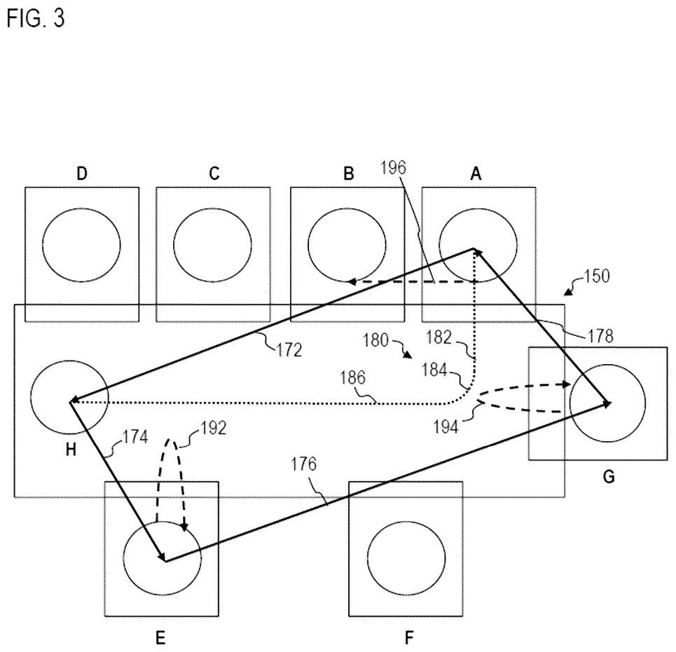

FIG. 3 provides a plan view of an exemplary handling sequence for a substrate W within a processing system. The handling sequence of FIG. 3 can be employed to transport a substrate W formed by a semiconductor wafer. Each of the stations A-G is formed as an FOUP (Front Open Unified Pod) connected to an Equipment Front End Module (EFEM) or Front Interface (FI) 150 included within the substrate processing system. Station H is, for example, a pre-aligner station located within the EFEM. A robot located within the EFEM, can perform a handling sequence by beginning at station A (or alternatively at station B, station C, or station D), moving substrate W to pre-aligner or aligning station H, subsequently moving the substrate W to station E, moving the substrate to side storage station G, and finally returning the substrate W to station A, as illustrated in the solid lines 172, 174, 176, 178 of FIG. 3. Solid lines 172, 174, 176, 178 represent the flow of the handling sequence and not the actual path of robot 12 or substrate W. An exemplary path representing an actual motion path of substrate W between Station A and Station H is illustrated by a dotted line 180 extending therebetween. This path 180 includes both straight line segments 182, 186 and an arc-shaped or curved segment 184 having a constant radius. The path alternatively could include a parabolic curve. After the substrate W is transported to stations E and G, the robot 12 can withdraw from the corresponding station, as illustrated by the dashed lines 192 and 194 shown at these stations. At each withdrawal, the robot 12 can enter a standby position to await processing of the substrate W, as represented by dashed lines 192 and 194, or perform a transfer of another substrate W, as represented by dashed line 196 in which robot 12 moves within the FI from station A to station B without a substrate W. Thus, the robot 12 is configured to transport a substrate W between multiple origins and destinations within the FOUPs and the FI. The robot 12 is further configured to transfer substrate W by first acquiring the substrate W and placing substrate W on a surface S of third arm 20, moving substrate W to a destination station, transferring the substrate W to a predetermined position within the destination station, and subsequently withdrawing from the destination station without the substrate W.

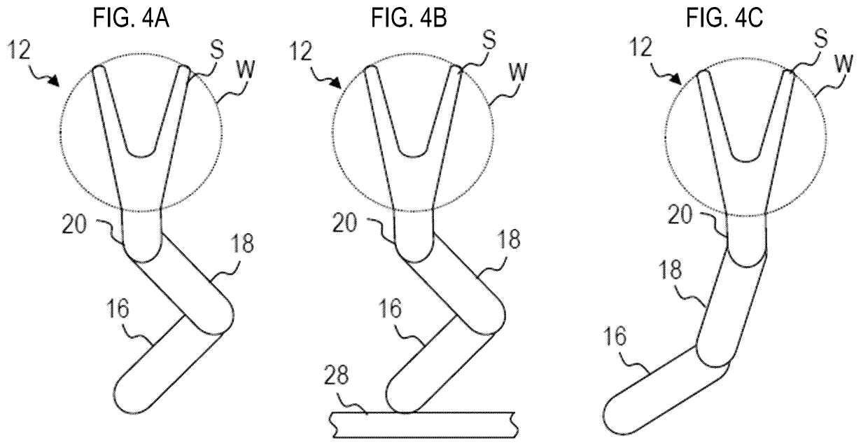

FIGS. 4A-4C depict a series of exemplary robot 12 configurations. Each of FIGS. 4A-4C depicts at least one substrate W and surface S of third arm 20. FIG. 4A illustrates a single arm unit formed by at least two arm members (individual first and second arms 16, 18) and a passive third arm 20. FIG. 4B is similar to the single arm of FIG. 4A, and also includes a track 28 that can impart translational motion to the robot 12 along the track 28. FIG. 4C illustrates a single arm unit similar to that of FIG. 4A, but includes an active third arm 20 that is driven by drive unit 24D. In addition, the invention could be used in conjunction with various configurations of dual arm unit robots.

Third arm 20 can include an end effector such as edge-gripping and/or vacuum devices which can provide additional security to substrate W supported on surface S of third arm 20. Edge-gripping devices contact an outer circumferential area of substrate W, while suction or vacuum devices supply suction to an underside of substrate W.

It is noted that the drawings depict a bifurcated Y-shaped end effector; however, the end effector vision with laser assist device can be utilized with other end effector configurations, such as, paddle blade end effectors (e.g., a narrow and/or straight single blade), a U-shaped end effectors, or any other desired end effector shape could be used depending upon the shape of the object being handled and/or the surrounding area in which the object is being moved.

Embodiments of the present disclosure advantageously provide an end effector that can sense a vertical position of a warped wafer.

Heterogeneous integration and warped wafers are becoming more common within semiconductor chip manufacturing. Given pre-existing standards for cassette pitch and physical limitations on minimum blade thickness, it has become increasingly more difficult to handle warped (e.g., taco shaped warpage, bowl shaped warpage, etc.) or thicker wafers given the uncertainty of the magnitude of their warpage.

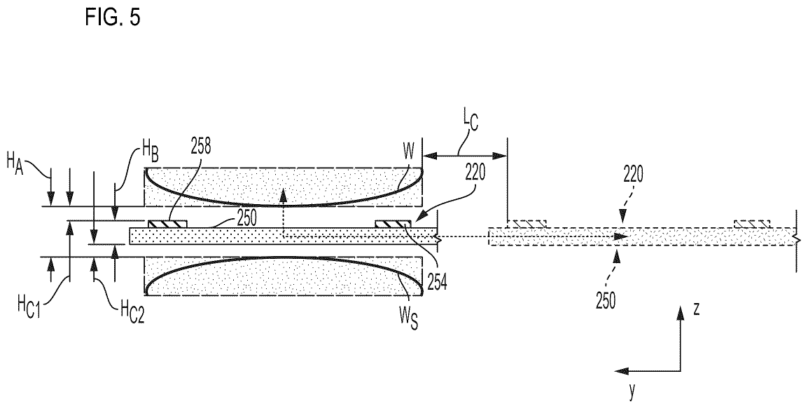

Of particular concern is the ability to either extend or retract the robot end effector between two wafers without collision or drag out, as shown in FIG. 5. FIG. 5 shows a side view of a blade 250 of an end effector 220 (see, e.g., FIG. 6) having a pads 254 on a proximal end thereof and a pad 258 on a distal end thereof (an additional pad is provided on the distal end as shown in FIG. 6). FIG. 5 shows a wafer W with an exaggerated representation of a possible curved configuration above the blade 250 of the end effector 220, and a wafer W_{S} with an exaggerated representation of a possible curved configuration. It is desirable to be able to extend (shown in solid lines) and retract (shown in phantom lines) the robot end effector 220 between two wafers W, W_{S} without collision or drag out, as shown in FIG. 5.

There is a need to sense the vertical position of the wafer(s) relative to the end effector, in other words, the vertical clearance, H_{C1} and/or H_{C2}, prior to a potential collision. As seen in FIG. 5, the vertical clearance H_{C1} represents the clearance between an uppermost surface of the end effector 220, which in this case is an uppermost surface of pad 258 and/or an uppermost surface of pad 254 (and/or an uppermost surface of pad 256 shown in FIG. 6), and a lowermost surface of the wafer W. The vertical clearance H_{C2} represents the clearance between an uppermost surface of the wafer W_{S} and a lowermost surface of the blade 250 of the end effector 220. The uppermost surface of the end effector 220 is a closest point of the end effector 220 to the lowermost surface of the object, such as wafer W.

There is a need to make this determination some distance (e.g., 25 mm, 75 mm, etc.), L_{C}, away from the collision such that the robot has sufficient time to adjust its position or simply slow down to a stop to avoid the collision.

It is noted that the drawings depict the end effector vision with laser assist device being used to detect/sense semiconductor wafers; however, the object of concern could be a wafer, a wafer holder, an obstruction, other type of object being handled by the end effector, etc. Further, while the drawings depict the end effector vision with laser assist device being used to detect/sense generally round-shaped semiconductor wafers, the wafer could be any type or shape of wafer packaging or wafer panel, such as, a Wafer Level Packaging CoWoS (Chip on Wafer on Subtrate), a Panel Level Packaging CoPoS (Chip on Panel on Substrate), etc. For example, the object could be a rectangular wafer panel configured as a 310 mm×310 mm panel with a warpage of 10 mm.

FIG. 5 also shows a vertical clearance HA between the lower most surface of the wafer W and the uppermost surface of the wafer W_{S}. FIG. 5 also shows a vertical height of the blade 250 of the end effector 220 between the uppermost surface of pad 258 and/or the uppermost surface of pad 254 (and/or the uppermost surface of pad 256 shown in FIG. 6), and the lower most surface of the blade 250 of the end effector 220.

Given the potential warpage of the wafer, wafer pads, such as pads 254, 256, and 258, are typically located on the end effector to support the wafer at its extremities. These pads, bumpers, or retaining features will often be the high point of the end effector and thus the objects most prone to collision with the wafer.

Note that the blade 250 of the end effector 220 itself can deflect due to gravity. Given this deflection, the blade is leveled such that the pads are coplanar relative to ground. The vertical excursion of the blade is tightly controlled. End effector vibration in the vertical direction is also a factor to consider.

The smart phone market has made high resolution cameras commercially available at relatively low cost. Laser diodes, such as those found in a laser pointer, are also available at reasonable costs. As shown in FIG. 6, a robot end effector 220 has been configured with some number of laser diodes (e.g., red laser (or first laser diode) 232, green laser (or second laser diode) 234, blue laser (or third laser diode) 236 in FIG. 6) and camera(s) (e.g., camera 240) built into a wrist portion 230 of the end effector 220 which allows for greater thickness. (Please note that FIG. 6 depicts a wafer W in a wafer holding position of the end effector 220; however, the present disclosure is, for example, concerned with possible contact between the end effector and the wafer during the process in which the end effector is moving to pick up the wafer (i.e., prior to the wafer being in the wafer holding position). However, the presence of the addition components (e.g., camera(s), laser(s), etc.) should not interfere with the normal operation of the end effector.)

FIG. 6 depicts an embodiment of a third arm 20 in the form of an end effector 220. The end effector 220 includes a base portion 222, a wrist portion 230, and a blade portion (or blade) 250. The base portion 222 has a pivot hole 224 about which the end effector 220 can pivot with respect to second arm 18, for example, when driven in rotation by drive unit 24D, for example. The base portion 222 has an upper surface 222a upon which a graphics processing unit (GPU) and/or central processing unit (CPU) 226 can be provided on a printed circuit board (PCB) 228. The GPU/CPU 226 and/or the PCB 228 are connected to a robot controller, such as control unit 22, via input cable 222a and output cable 222b.

In addition, at the wrist portion one or more laser diode(s) are provided, such as red laser 232, green laser 234, and blue laser 236, and one or more camera(s) are provided, such as camera 240. The laser(s) and camera(s) are connected to the GPU/CPU 226 and/or the PCB 228 for communication therewith. In this example, the red laser 232 is configured to emit a red laser beam 233 in a first direction D1, the green laser 234 is configured to emit a green laser beam 235 in a second direction D2, and the blue laser 236 is configured to emit a blue laser beam 237 in a third direction D3. In this example, the red laser 232 is configured to emit the red laser beam 233 as first laser light in a first wavelength range (i.e., in a red light wavelength range, such as 620-770 nm), the green laser 234 is configured to emit the green laser beam 235 as second laser light in a second wavelength range (i.e., in a green light wavelength range, such as 520-570 nm), and the blue laser 236 is configured to emit the blue laser beam 237 as third laser light in a third wavelength range (i.e., in a blue light wavelength range, such as 450-490 nm). Note that other colors could be used and that the red, green, and blue lasers described herein could be interchanged.

The graphics processing unit (GPU) and/or the central processing unit (CPU) 228 can be provided on the printed circuit board (PCB) 226 within the wrist. The input/output cables 222a, 222b from the wrist to forearm typically has four channels (lines/wires/cables). One is for wafer mapping. One is for a wafer on blade (WOB) sensor. Thus, there are two remaining lines that are readily available allowing for four states: proceed; move up; move down; and stop. Alternatively, an Ethernet cable can be sent to the wrist.

The blade portion 250 has an upper surface 252 configured to act as a surface that supports a substrate W. The blade portion 250 has a proximal end with a pad 254, and a distal end that has two tines that each have a pad, namely, pad 256 and pad 258, respectively. The pads 254, 256, 258 are provided to contact a lower surface of the substrate W when the end effector 220 support the substrate W.

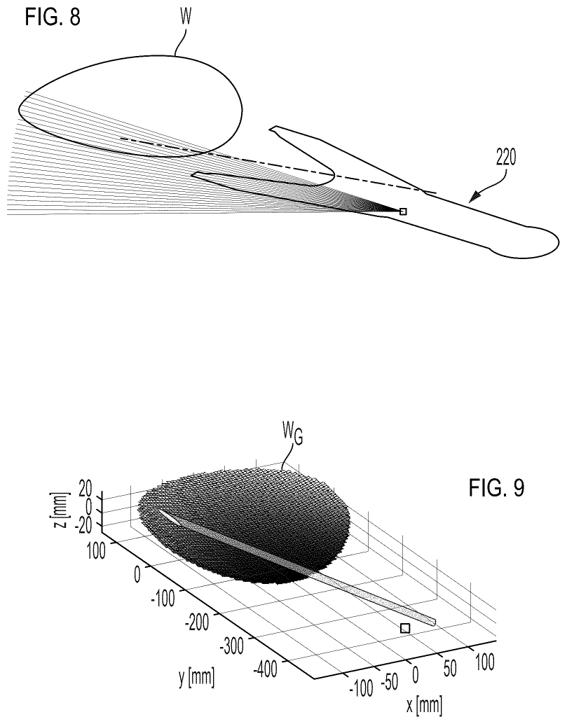

The end effector blade portion 250 will approach the warped wafer as shown in FIGS. 7, 8, and 9. FIG. 7 is a side view of a portion of the end effector 220 (not drawn to scale) approaching the warped wafer W in a y_{c} direction. FIG. 8 is a schematic perspective view of the end effector 220 approaching the warped wafer W. FIG. 9 is a graphical representation of the view the warped wafer W_{G} in an x-y-z coordinate system. As shown in FIG. 7, a dimension of particular interest is a clearance H_{C} that is a difference between an uppermost point of the pad (e.g., pad 258) and a lowermost points of the wafer/obstruction W in order to avoid collision and/or more precisely control movement of the end effector 220 using the robot arm.

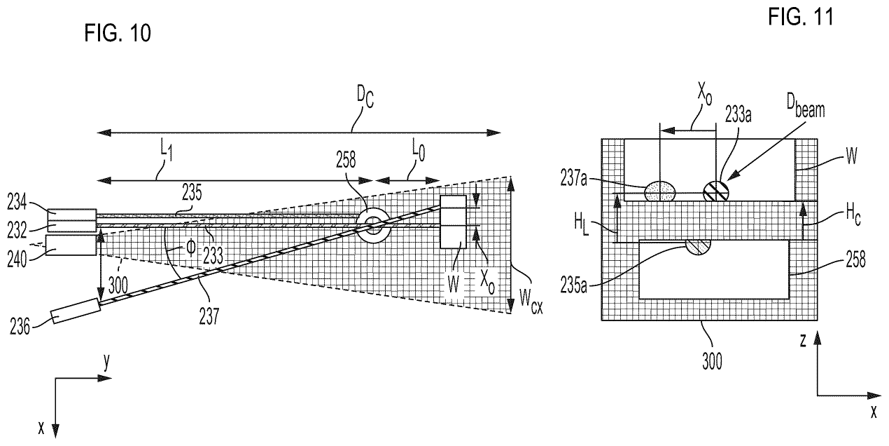

Thus, the primary concern is the high points of the end effector, represented as a wafer pad in the figures, contacting the wafer, represented as a wafer obstruction. As shown in the figures, such as FIGS. 10 and 11, a camera 240 positioned at the wrist can be selected such that its working length, Dc, can clearly view the area of concern for the end effector within the camera's field of view 300 having a width W_{CX}. There is typically not enough ambient light in the environment for the camera to easily distinguish between the end effector and the wafer. The addition of diffuse light would not significantly improve the problem. Rather, a series of concentrated beams could clearly identify a location on the wafer or end effector and be readily interpreted by the camera. In this example, the red laser 232 is configured to emit the red laser beam 233 toward the wafer W to form a red area 233a on the wafer W, the green laser 234 is configured to emit the green laser beam 235 to the upper edge of the pad 258 to form a green area 235a on the pad 258, and the blue laser 236 is configured to emit the blue laser beam 237 toward the wafer W to form a blue area 237a on the wafer W, as shown in FIGS. 10 and 11.

The lasers must all be calibrated to be parallel with the x-y plane of the blade, orthogonal to the dimension of interest, and have a z offset, H_{L}, between the point of interest on the blade (e.g., wafer pad) and the wafer obstruction (i.e. the wafer of concern). The end effector laser (i.e., green laser 234) will be trained on the end effector (e.g., on the pad 258 of the end effector 220).

The laser(s) can be offset by an angle from the camera 240 in either direction. Generally, at least one laser per pad at the distal end of the blade is desired. It is possible to use one camera to sense both pads/lasers or a camera could be provided for each pad.

A laser beam is comprised of a concentration of parallel light rays that exist within a given beam diameter. For a given condition, some, none, or all of a given laser beam will contact the wafer/pad and light that contacts wafer/pad will be diffusely reflected back to the camera(s) for observation as shown in the figure below. In the example shown in this section, a green laser is directed toward a presumed location of an uppermost feature of the end effector (e.g., an upper edge of the wafer pad), while a blue laser and a red laser are each is directed toward a presumed location of a lowermost feature of object of concern (e.g., a wafer (e.g., a lowermost edge or lowermost bottom surface of the wafer), wafer holder, obstruction, etc.). Note that these positional relationships could be inverted (i.e., the obstruction could be below the end effector and the laser(s)/camera(s) provided on the lower surface of the end effector in the height direction such that the clearance is between a lowermost surface of the end effector and an uppermost surface of the obstruction).

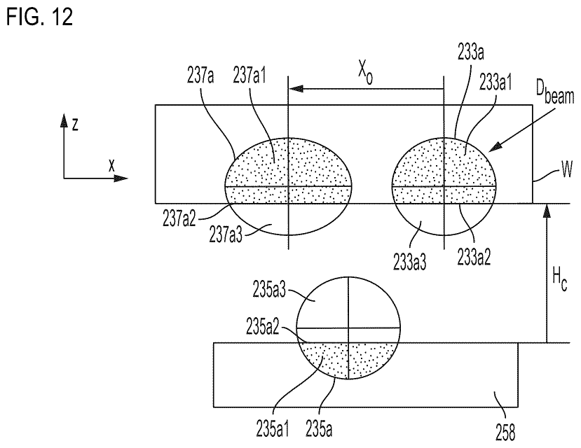

FIG. 12 depicts an enlarged version of FIG. 11 that shows a side view of the wafer W and pad 258 as viewed by the camera. In this example, the red laser 232 is configured to emit the red laser beam 233 toward the wafer W to form the red area 233a on the wafer W. It is noted that a first portion 233al of the red laser beam 233 contacts the wafer W and a second portion 233a3 of the red laser beam 233 does not contact the wafer W. The red area 233a has a line 233a2 at a lowermost edge of the first portion 233a1. The green laser 234 is configured to emit the green laser beam 235 toward the pad 258 to form the green area 235a on the pad 258. It is noted that a first portion 235al of the green laser beam 235 contacts the pad 258 and a second portion 235a3 of the green laser beam 235 does not contact the pad 258. The green area 235a has a line 235a2 at an uppermost edge of the first portion 235a1. The blue laser 236 is configured to emit the blue laser beam 237 toward the wafer W to form the blue area 237a on the wafer W. It is noted that a first portion 237al of the blue laser beam 237 contacts the wafer W and a second portion 237a3 of the blue laser beam 237 does not contact the wafer W. The blue area 237a has a line 237a2 at a lowermost edge of the first portion 237a1.

If an obstruction exists, the camera 240 will be able to see the first portion 233al of the red laser and the first portion 237al of the blue laser contacting the wafer/obstruction. In the vision algorithm, the R-G-B values of the camera image can be easily and quickly determined and the pixels associated with each laser identified. However, this concept is not limited to light in the visible spectrum. Thus, via the pixel color and position within the image, the lowermost points of the red laser (i.e., along line 233a2) in the camera array coordinate frame will be identified, as well as the uppermost points of the green laser (i.e., along line 235a2) in the camera array coordinate frame. The difference between the uppermost point of the pad and the lowermost points of the wafer/obstruction can then be used to calculate the clearance, H_{C}, in order to avoid collision and/or more precisely control movement of the end effector using the robot arm. Thus, we will identify which pixels within the image are receiving the light with the frequency (color) of interest. Through calibration, we can determine the height of the object associated with the pixel relative to either a calibrated point on the pad (i.e. predetermined closest point) or a pixel associated with light on the pad.

The green laser beam 235 typically has the highest light intensity and is the easiest to read on the camera 240. The blade 250 of the end effector 220 is a structural member subject to vibration primarily in the z axis with resonant modes in the 10 Hz to 20 Hz range (check update rate of camera for aliasing) and an amplitude of about 1 to 2 mm. As shown, the green laser beam 235 can be positioned such that it is just touching the end effector's point of interest (i.e., the uppermost point/edge). The end effector laser beam can run parallel with the plane of the end effector. Some portion of the beam should interact with the undisplaced point of interest. The amplitude of blade vibration can be ascertained by counting the green pixels over a period of time. The beam diameter can be selected/designed to capture the maximum anticipated amplitude.

The Offset Wafer Laser (blue laser beam 237 in the depicted example) will be mounted at an angle, ϕ, with respect to the end effector laser (green laser beam 235 in the depicted example). The offset laser would also be parallel with the x-y plane of the end effector. The two lasers can intersect in the x-y plane at a point of interest at a known distance, L₁, as seen FIG. 10. With the camera calibrated, the horizontal distance (pixels), x_{O}, between the blue dot (or blue area) 237a and the green dot (or green area) 235a (or red dot or red area 233a) can be calculated.

The clearance, H_{C}, between the end effector and the wafer obstruction can be ascertained.

The approximate distance from the point of interest to the wafer obstruction can be ascertained through the following equation,

L_{O}=x_{O}/tan(ϕ)

From this distance, the controller of the robot can determine how aggressively the end effector needs to be slowed down. It is also possible to use this distance to distinguish between an obstacle that is in close proximity versus an obstacle that is safely off in the distance.

In reality, the red laser 232 may be superfluous (or secondary wafer laser).

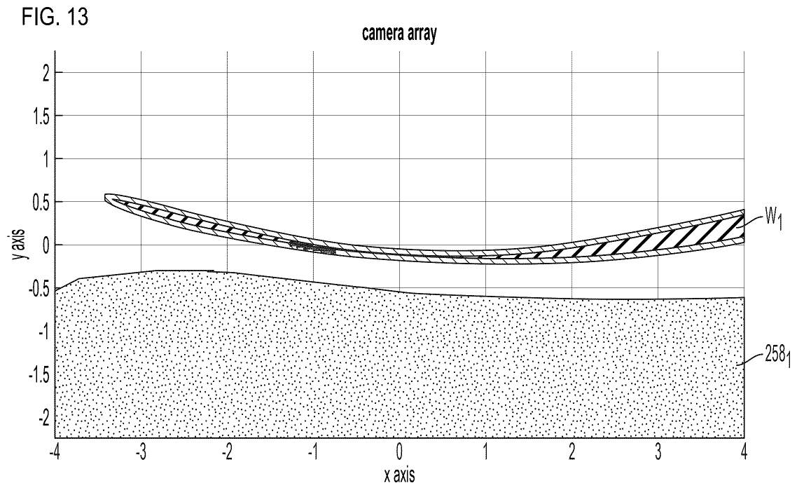

A simulation of the camera image of a blade and the beam striking a warped wafer is shown in FIG. 13, which graphically shows a warped wafer W₁ and pad 258₁.

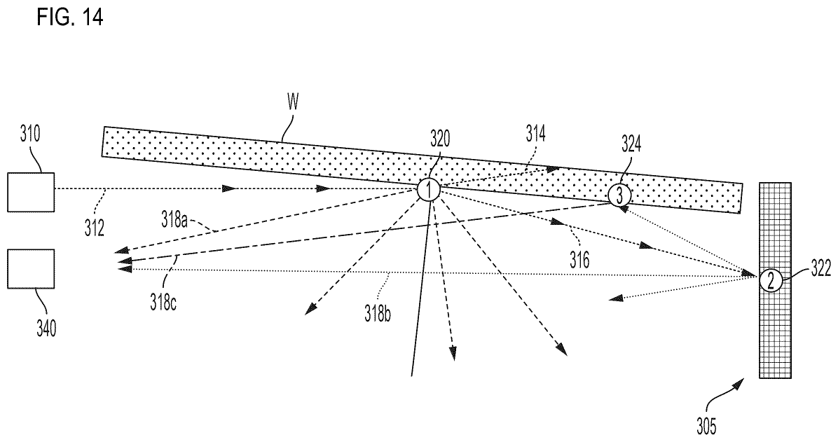

FIG. 14 depicts various types of reflection that can occur off a wafer W and/or wall 305 of the processing chamber or FOUP during a sensing operation. During the sensing operation, a light source 310 (e.g., red laser 232, green laser 234, blue laser 236) transmits a beam of light toward the wafer W and/or the wall 305, and a light measurement device 340 (e.g., camera(s) 240) sense light reflected back to the light measurement device 340.

The invention projects/focuses light on the wafer and observes this light with a sensor such that the position of the wafer in relation to the end effector can be determined, and, in particular, the clearance height between the wafer and the blade/pad can be determined.

Both a glass wafer and a silicon wafer are highly reflective. A ray of light (or incident ray) 312 can travel from the light source 310 to point of interest \textcircled{1} 320.

The majority of the light traveling from the light source 310 to point of interest \textcircled{1} 320 on the wafer W will bounce off the wafer in specular reflection, such as specular reflection ray 316, at an angle symmetric with the normal to the surface. It is possible, but it is unlikely that any light will return to the camera 340 with pure specular reflection. In fact, it is desired to avoid specular reflection back to the camera 340. In this method, we are interested in/searching for primary diffuse reflection.

The ray of light 312 will have some amount of primary diffuse reflection from the wafer, traveling in all directions from the point of contact, such as point of interest \textcircled{1} 320. This is the primary ray of light we wish to observe. For example, as shown in FIG. 14, a ray of primary diffuse reflection 318a travels back to camera 340.

In the case of a glass wafer, some amount of light reaching point of interest \textcircled{1} 320 will be refracted into the glass and will strike the substrate above, such as refracted ray 314.

Some amount of light will travel from point of interest @ 320 to point of interest \textcircled{2} 322 on the back wall of the front opening unified/universal pod (FOUP) through specular reflection. Secondary diffuse reflection 318b or specular reflection from point of interest \textcircled{2} 322 can return back to the camera 340 and can be a source of confusion, and therefore it should be distinguished from the desired primary diffuse reflection 318a.

Diffuse reflection from point of interest \textcircled{2} 322 can travel to the reflective surface of the wafer W at point of interest \textcircled{3} 324. Light from point of interest \textcircled{3} 324 can travel back to the camera via tertiary diffuse reflection 318c or specular reflection and can be a source of confusion, and therefore it should be distinguished from the desired primary diffuse reflection 318a.

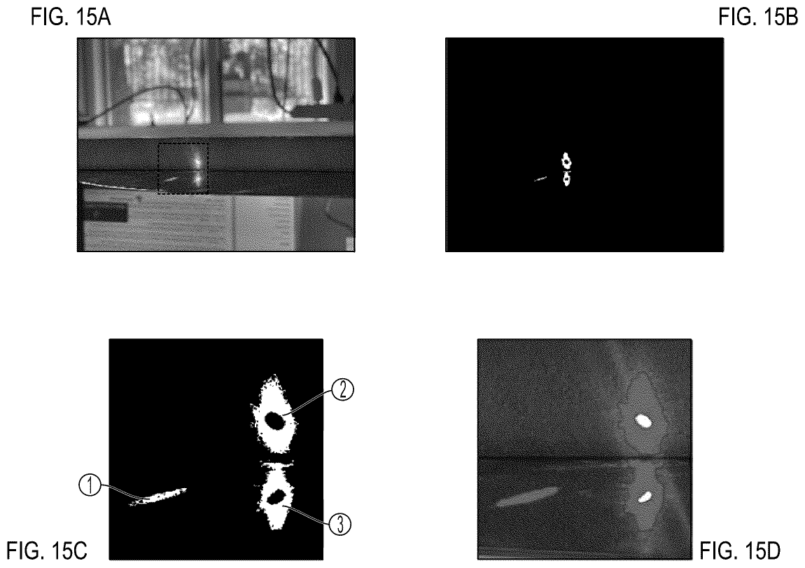

An example of primary, secondary, and tertiary diffuse reflection is shown in the images of laser light on a silicon wafer in FIGS. 15A-15D. FIG. 15C shows labeled points of interest including point of interest 1, point of interest 2, and point of interest 3.

### Issue of Projection

The following delves into the issues that would be associated with normal vision or with having a single camera with parallel lasers. This section further establishes the need for an offset beam.

### Parallel Lasers, Single Camera

### Perfectly Parallel Wafer

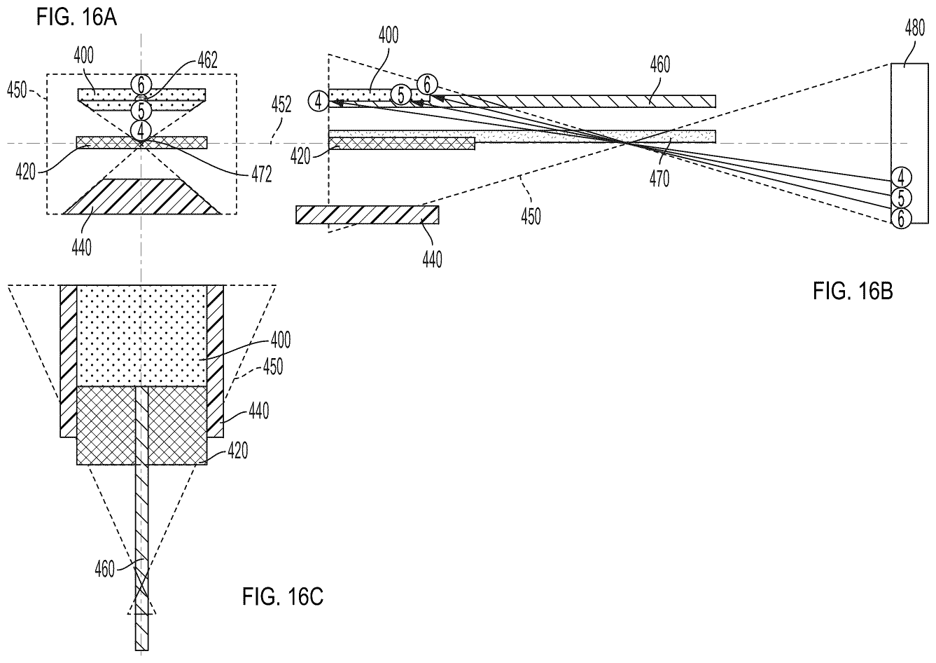

FIGS. 16A-16C depict diagrams of parallel lasers and single camera arrangement. FIG. 16A depicts a front perspective view of a diagram of such an arrangement as would appear in a camera image, FIG. 16B depicts a side view of a diagram of such an arrangement, and FIG. 16C depicts a top view of a diagram of such an arrangement. FIGS. 16A-16C schematically depict wafer (or other obstruction) 400, a pad 420 of the end effector, and a blade 440 of the end effector. FIGS. 16A-16C further schematically depict a field of view 450 of a camera 480, a red laser beam 460 and a green laser beam 470. The red laser beam 460 would form a red area 462 on the wafer 400 and the green laser beam 470 would form a green area 472 on the pad 420.

If the wafer 400 is perfectly parallel but vertically offset from a focal axis 452 of the camera 480, we will see the underside of the wafer 400 through projection, as can been seen in the perspective view of FIG. 16A. Note that point of interest \textcircled{6} is forward facing. However, point of interest \textcircled{4} and point of interest \textcircled{5} are also visible in the camera image as seen in FIG. 16A. The lines pass through the vanishing point located along the focal axis 452

With just simple vision and the complexity of projection, it would be very difficult to distinguish between a wafer that is perfectly parallel and one that is tilted slightly if the wafer does not lie perfectly on the focal axis (which it would most likely not lie perfectly on the focal axis). If we project a laser that is perfectly parallel with the focal axis and the wafer onto the wafer, the laser would only strike the front face of wafer and not be seen on the underside of the wafer. For example, the laser would show up at point of interest \textcircled{6} but not on point of interest \textcircled{4} and point of interest \textcircled{5}.

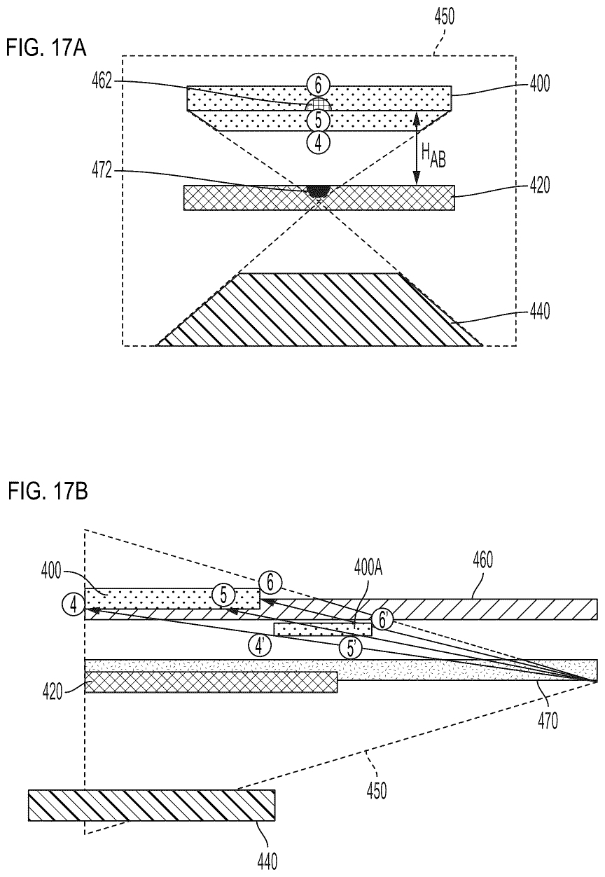

Even in this nearly perfect case, as further depicted in FIG. 17A, the number of pixels can be counted between the two images, but the vertical clearance between the wafer (or obstruction) 400 and the pad 420 of the end effector, H_{AB}, could not be deterministically ascertained. This is because the depth of the wafer 400 relative to the pad 420 would not be known. For example, as shown in FIG. 17B, it would not be possible to determine if the wafer 400 is a large body (labeled as 400) that is farther away (i.e., at points \textcircled{4}, \textcircled{5}, \textcircled{6}), or a smaller body 400A that is closer to the camera (i.e., at points \textcircled{4}′, \textcircled{5}′, \textcircled{6}′).

### Parallel Lasers, Wafer Out of Parallel

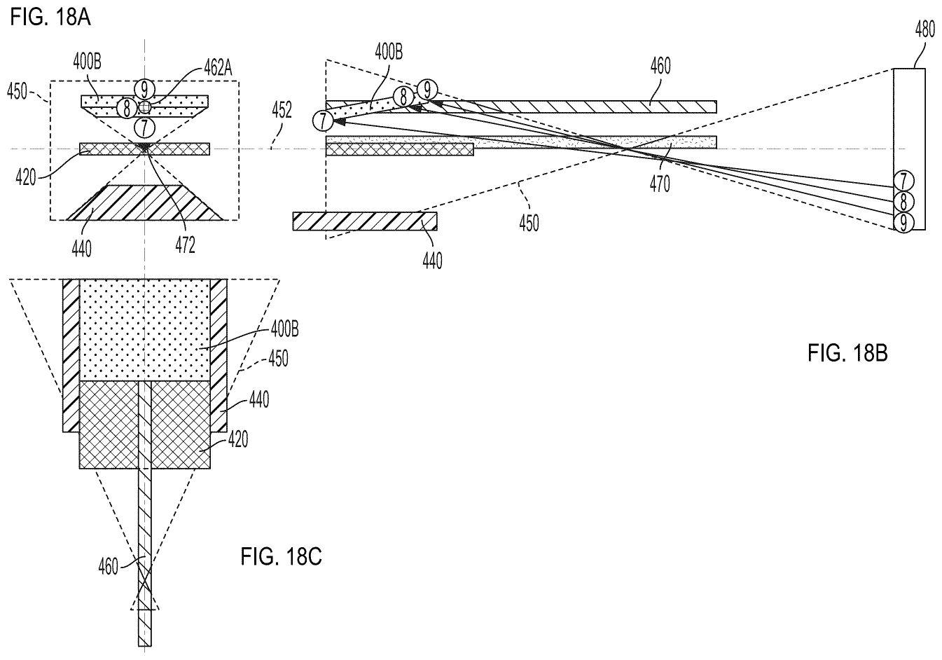

As shown in FIGS. 18A-18C, if the wafer 400B is not perfectly parallel with the laser (which will often be the case), the laser will project onto the underside of the wafer 400B.

We can now ascertain that the laser is striking the wafer 400B at points of interest \textcircled{7}, \textcircled{8}, and \textcircled{9}, but there is still no deterministic way of knowing the vertical clearance between the bodies, H_{AB}.

As we intend to show, by projecting the laser at an angle and distance away from the camera, we can ascertain the height and distance of the point of interest.

### Stereo Vision

Two cameras, offset from one another, could be used to identify a point of interest on the wafer. The two cameras can be calibrated to understand their position and orientation with respect to one another and the environment. The two cameras need to simultaneously identify a unique feature on the object of interest. The geometry of the wafer is not inherently unique. There are no inherent features which can be identified. Thus, a laser will be required to be shown on a feature of interest on the wafer.

### Geometry: One Camera, One Wafer Laser

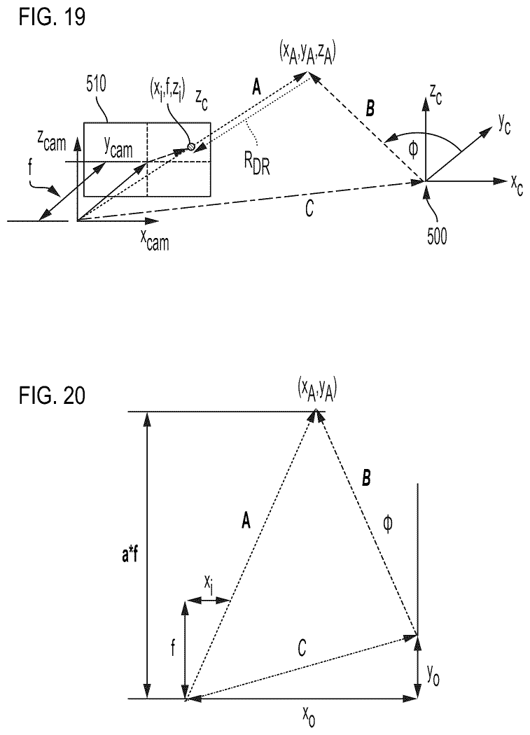

The following depiction and corresponding depiction in FIG. 19 define equations to implement the concept.

In FIG. 19, a laser light source 500 is provided. A camera coordinate frame, cam, is affixed at a focal point of the camera. The camera sensor is a distance, f, in the y direction. The camera sensor is in the x-z plane of the camera coordinate frame and has a camera image 510.

Vector A has an origin at the camera coordinate frame and an end point at a point of interest (x_{A}, y_{A}, z_{A}). A ray of diffuse reflection R_{DR} will travel from the point of interest (x_{A}, y_{A}, z_{A}), along the vector A in the opposite direction, arriving at the camera sensor. The point on which the light hits the sensor is defined as (xᵢ, f, zᵢ). We can interpret xᵢ, zᵢ, and f based on knowledge of the camera geometry and the specific pixel associated with the image. More specifically, we will look for light that is near the frequency of the laser (e.g., red light, blue light, green light). From the camera image and the focal length, we know the direction of the vector A in the camera coordinate frame but the scaled magnitude, a, is unknown. We represent the vector A as follows:

$$A = a * {[ {x}_{1} , f , {z}_{i} ]}^{T} .$$

The laser diode will be statically offset from the camera by vector C as defined as follows:

$$C = {[ {x}_{o} , {y}_{o} , {z}_{o} ]}^{T} .$$

Given that the beam will have some thickness, the height of the light in the z axis, z_{O}, will be unknown.

The light emanating from the laser 500 will be oriented such that the beam is parallel with the x-y plane and is at an angle ϕ with respect to the y axis and about the z axis as shown in FIG. 19. The vector B is defined as a beam of light emitted from the laser light source 500 and contacting the point of interest (x_{A}, y_{A}, z_{A}). Again, we know the orientation of the beam, but we do not know its length, b.

$$B = b * {[ - sin ( ϕ ) , cos ( ϕ ) , 0 ]}^{T}$$

We may observe the relationship between the vectors:

$$A = C + B .$$

We have three equations in the three unknowns: a, b, and z_{O}.

If we observe the x and y component of the equation, we can see that we have two equations in the two unknowns, a and b.

$$a * {x}_{i} = {x}_{o} - b * sin ( ϕ )$$

$$a * f = {y}_{o} + b * cos ( ϕ )$$

$$a * {x}_{i} = {z}_{o}$$

Solving for the unknown, a, from the first two equations,

$$a = ( {x}_{o} * cos ( ϕ ) + {y}_{o} * sin ( ϕ ) ) / ( {x}_{i} * cos ( ϕ ) + f * sin ( ϕ ) ) ,$$

we can determine the height of the point of interest in the camera coordinate frame,

$$\begin{matrix}{z}_{A} & = {z}_{o} \\ & = a * {z}_{i} \\ & = {z}_{i} * ( {x}_{o} * cos ( ϕ ) + {y}_{o} * sin ( ϕ ) ) / ( {x}_{i} * cos ( ϕ ) + f * sin ( ϕ ) ) .\end{matrix}$$

If the camera offset is small, the equation simplifies to

$${z}_{A} = {z}_{i} * ( {x}_{o} + {y}_{o} * ϕ ) / ( {x}_{i} + f * ϕ ) .$$

We can determine the distance of the point of interest along the z axis in the camera coordinate frame,

$$\begin{matrix}{y}_{A} & = a * f \\ & = f * ( {x}_{o} * cos ( ϕ ) + {y}_{o} * sin ( ϕ ) ) / ( {x}_{i} * cos ( ϕ ) + f * sin ( ϕ ) ) .\end{matrix}$$

With these two values, we can establish the position of a point of interest in the camera coordinate frame.

### Importance of Offset

We may observe the geometry in the x-y plane, as shown in FIG. 20.

### Generalized Beam Direction

The above development represented the idealized solution. In reality, the laser light may not lie perfectly in the x-y plane of the camera coordinate frame. We can characterize its direction which will have components, bₓ, b_{y}, and b_{z}. Thus, we wish to solve for the unknowns, a, b, and z_{O}.

The equation can be written to collect the unknowns,

$$[ \begin{matrix}{x}_{i} & - {b}_{x} & 0 \\ f & - {b}_{y} & 0 \\ {z}_{i} & - {b}_{z} & 1\end{matrix} ] \{ \begin{matrix}a \\ b \\ {z}_{0}\end{matrix} \} = \{ \begin{matrix}{x}_{o} \\ {y}_{o} \\ 0\end{matrix} \}$$

Which can be written,

$$X * D = H$$

We can solve for the unknown vector D by multiplying through the inverse of X.

$$D = {X}^{- 1} * H$$

### Least Squares Averaging

We will capture a number of pixels illuminated by the diffuse reflection of the laser beam within a given image. We can find the average value associated with a grouping of pixels. We can do so with the least squares approximation where X would be a 3*n×3 matrix and H would be a 3*n vector where n is the number of associated pixels.

$${X}^{T} * X * D = {X}^{T} * H$$

$$D = {( {X}^{T} * X )}^{- 1} * {X}^{T} * H$$

### Laser Alignment

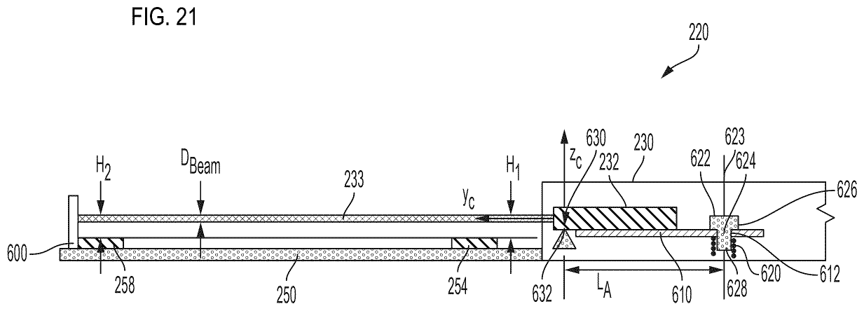

FIG. 21 shows the end effector 220 being leveled for laser alignment. The end effector 220 in FIG. 21 includes a leveling device that includes a leveling platform 610, a compressed spring 620 with an adjustment screw 622, and a fixed pivot 630. The leveling platform 610 pivots about fixed pivot 630 at a first end of the leveling platform 610. And the adjustment screw 622 has a head portion 626 and a threaded shaft 628 that extends through a hole 612 at a second end of the leveling platform 610. The threaded shaft 628 is threadedly engaged to the wrist portion 230 such that tightening of the threaded shaft 628 biases the second end of the leveling platform 610 downward about the fixed pivot 630. The threaded shaft 628 is threadedly engaged to the wrist portion 230 such that loosening of the threaded shaft 628 in conjunction with upward biasing of the compressed spring 620 against the second end of the leveling platform 610 biases the second end of the leveling platform 610 upward about the fixed pivot 630.

Note again that the end effector 220 will be leveled such that high points of the blade (e.g., pads 254, 256, and/or 258) will be leveled with respect to ground. As detailed above, it is critical that the laser be parallel and precisely, vertically positioned with respect to the horizontal plane defined by high points of the blade. As shown in FIG. 21, the laser diode (e.g., red laser 232) must be precisely positioned with two degrees of freedom to achieve the height and parallelism necessary. We can do so by establishing two points, point 632 at the fixed pivot 630 and point 624 at the adjustment screw 622, separated by a distance, L_{A}.

The positioning of point 632 and point 624 will determine the appropriate heights, H₁ and H₂, of the laser (e.g., red laser 232) from the pads 254 and 258, respectively. The dimension (height), H₁, being close to the laser can be established by the tolerance stack up from the pad 254 to the point 632. Point 632 will have a fixed pivot 630 allowing the laser 232 to rotate slightly. The laser diode will be affixed to the leveling platform 610 with preloaded adjustment screw 622 at point 624. Adjusting the screw 622 at point 624 (i.e., along axis 623) will allow us to properly position the laser 232 at the height, H₂. A leveling target 600 can be placed at the height, H₂. We can use feedback from the camera to determine and adjust the height of the beam, H₂.

### Camera Calibration

Camera calibration within an inertial coordinate frame requires some knowledge of the distance of the point of interest. In some cases, a laser measurement sensor is used in conjunction with a camera.

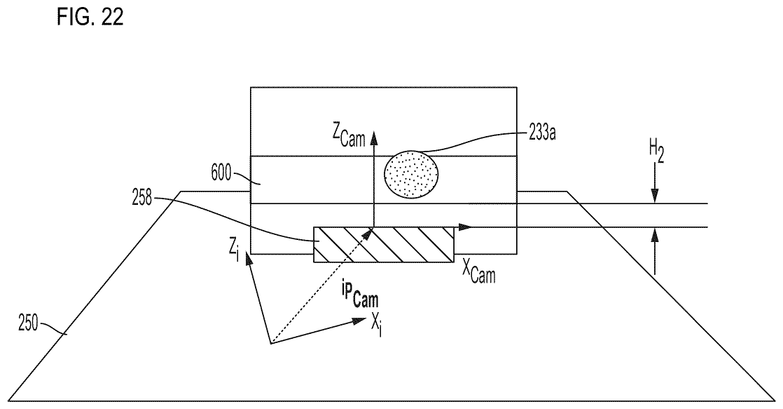

The same calibration or leveling target 600 that is used to position the beam can also be used to calibrate the camera. The camera image coordinate frame shown in FIG. 22, represented by the i coordinate frame, will not necessarily be aligned with the blade 250 and pads (e.g., pad 258).

However, with the calibration target 600, we can ascertain a translation and rotation matrix to establish the desired camera coordinate frame. The appropriate calibration vector and rotation matrix would be stored on the printed circuit board.

### Wafer Presence

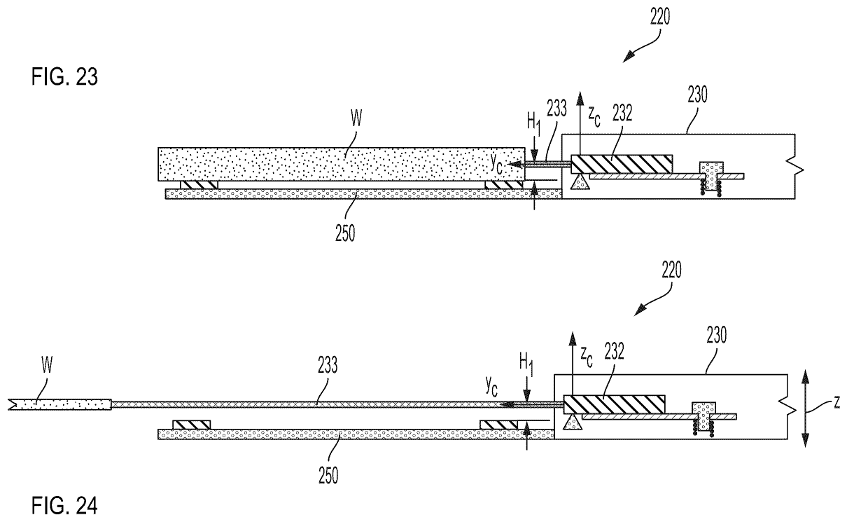

When a wafer is present, there is the potential for the laser and camera system to be able to serve the added purpose of sensing the presence of the wafer. Thus, as shown in FIG. 23, the laser 232 and camera could be used to determine the presence or absence of a wafer W on the blade 250. This may eliminate the need for an added sensor.

### Vertical Scanning: Mapping

There is the potential for the laser and camera system to sense a vertical position of a wafer or a series of vertically positioned wafers, for example, as shown in FIG. 24. The end effector 220 can be moved in the z direction, for example, at a constant velocity, and the position of the wafer W captured using the laser (e.g., laser 232) and camera (e.g., camera 240 in FIG. 6).

### Wafer Profile Imaging

The end effector will typically travel straight into a cassette in the y direction. The present invention as discussed above allows the robot to observe the clearance between the high points of the blade and the wafer as the blade is being inserted between two wafers in normal operation. The blade can adjust its vertical position in z so as to avoid collision. Separate from this normal operation, we may also wish to inspect the wafer prior to insertion.

The present invention has the ability to sense the vertical position of a wafer some physical distance away from the end effector itself. With the blade outside the wafer cassette, we have the freedom to rotate the wafer about the z axis and translate the wafer in the x direction. We can devise a series of moves that move the end effector in x, y, z directions and rotation about a z axis to scan the wafer from a distance. With these moves in conjunction with image processing, we can develop a wafer profile. This information can be sent back to a host computer.

### Laser Diode Specification

The laser diodes used herein can be of known varieties of laser diodes (see, e.g., https://www.edmundoptics.in/knowledge-center/application-notes/lasers/fundamentals-of-lasers/#:˜: text=Specifications % 20of%20a %20Laser, the %201%2Fe2%20width), and can operate within the visible light spectrum of about 400 nm to 700 nm. However, this concept is not limited to light in the visible spectrum.

### Safety

Laser should be selected such that it is visible by the camera but does not present any human hazard. For example, the Center for Devices and Radiological Health (CDRH) warning label designations that correspond to the maximum amount of laser radiation emitted from the laser at a specific wavelength can be used as guidance, and such warning labels should be provided on all laser products. Such warning label designations include: Class 1-non-hazardous; Class 1M-safe as long as additional optical instruments are not used; Class 2-safe for accidental exposure <0.25s, the natural reflex blink will prevent this from damaging the eye; Class 2M-safe for accidental exposure <0.25s as long as optical instruments are not used; Class 3R-momentarily hazardous; Class 3B-hazardous, viewing of diffuse reflection is safe; Class 4-hazardous, viewing of diffuse reflection is also hazardous, fire risk.

### Beam Diameter

The laser beam diameters used herein can be of known configurations (see, e.g., https://www.thorlabs.com/catalogpages/obsolete/2017/L520P120.pdf.)

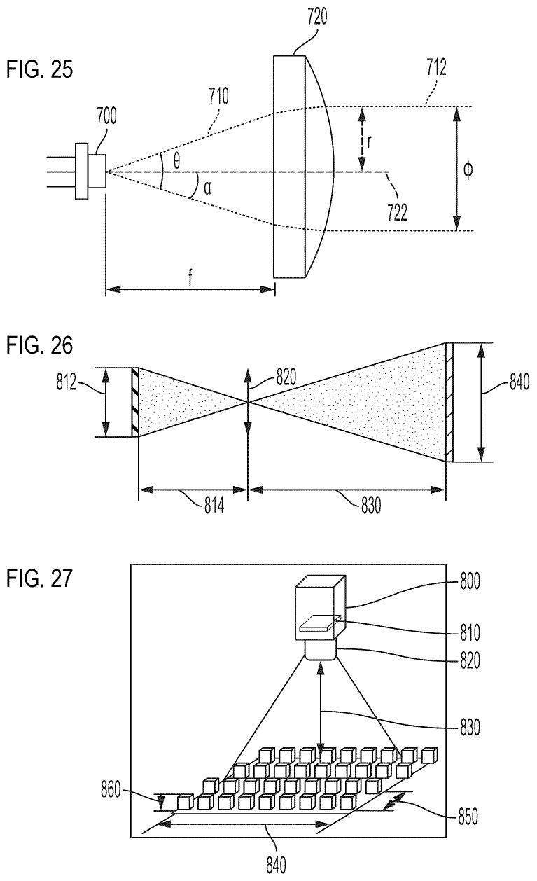

FIG. 25 depicts a laser diode 700 emitting light 710 having a divergent angle θ that travels through an aspheric lens 720, which produces a light beam 712 having a beam diameter ¢. The lens 720 has an optical axis 722. From such information, the focal length f can be determined using thin lens approximation. For example, using the equation:

f=r/tan α, where r equals ϕ/2 and a equalsθ/2.

Thus, for example, for a of 15 degrees and r equals 1.5 mm, the focal length would be equal to 5.6 mm.

### Life

The lasers used herein can be of known lifetime (see, e.g., https://worldstartech.com/what-determines-the-lifetime-of-a-laser-module/#:˜: text=Typical% 20lifetime %20of%20laser %20diode,to %20and %20including %20c omplete%20failure), such as 25,000 to 50,000 hours (2.8 to 5.7 years).

Typical lifetime of laser diode modules are 25,000 to 50,000 hours. If the laser diode temperature rises beyond the maximum operating temperature the long-term performance may degrade significantly, up to and including complete failure. If the laser diode's operating temperature is reduced by about 10 degrees, the lifetime will statistically double.

Laser module lifetime can be extended significantly by maintaining the case temperature at the low end of the operating temperature range. Heat sinks are recommended and must be used if the laser is operating constantly. Operating the laser modules at the low end of the recommended voltage range will also help to extend the lifetime of the laser.

### Cameras

The cameras used herein can be of known configuration (see, e.g., https://www.ni.com/en/support/documentation/supplemental/18/calculating-camera-sensor-resolution-and-lens-focal-length.html).

FIGS. 26 and 27 show schematic views of a camera 800 and features associated therewith. The camera 800 includes a sensor 810 having a sensor size 812, a focal length 814, a lens 820, a working distance 830, a field of view 840, a resolution 850, and a depth of field 860.

The x-y field of view is roughly 100 mm. We are preferably checking clearances of 1 mm to 0.1 mm. We would ideally be able to detect at least 10 pixels in that 0.1 mm. So, the resolution would be, 100 mm/(0.1/10)=10,000 pixels over the entire field of view.

Exemplary resolutions can include 12 megapixel (e.g., 4032 pixel×3024 pixel), 6 megapixel (e.g., 3072 pixel×2048 pixel), 5 megapixel (e.g., 2592 pixel×1920 pixel), 3 megapixel (e.g., 2048 pixel×1536 pixel), 1080p or 2.1 megapixel (e.g., 1920 pixel×1080 pixel), 0.9 megapixel or 720P (e.g., 1280 pixel×720 pixel), 4 CIF (e.g., 720 pixel×576 pixel), VGA (e.g., 540 pixel×480 pixel). Exemplary cameras can include Apple iPhone® Pro Max cameras having features such as: equivalent focal lengths (on 35 mm full-frame) of 13 mm, 26 mm, 65 mm; maximum apertures of f/2.4, f/1.6, f/2.2; actual focal lengths of 1.54 mm, 5.1 mm, 7.5 mm, 2.71 mm; lengths elements of 5, 7, 6.

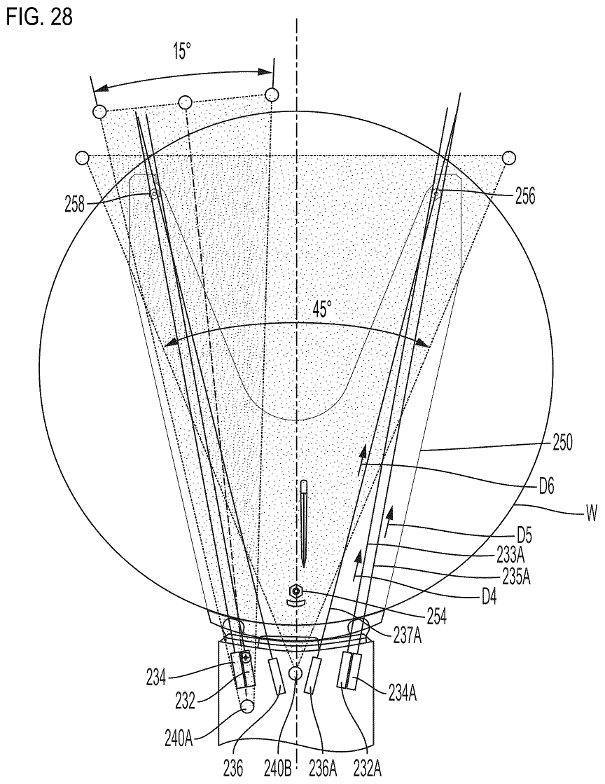

FIG. 28 depicts an embodiment including a narrow angle camera 240A having a narrow field of view diverging at a fifteen degree angle that encompasses only pads 258, and an additional camera 240B provided, in this embodiment, as a wide angle camera having a wide field of view diverging at a forty-five degree angle that encompasses each of pads 254, 256, and 258.

The embodiment shown in FIG. 28 includes the first laser diode 232, the second laser diode 234, and the third laser diode. This embodiment further includes a fourth laser diode 232A configured to emit a laser beam (e.g., a red laser beam) 233A in a fourth direction D4, a fifth laser diode 234A configured to emit a laser beam (e.g., a green laser beam) 235A in a fifth direction D5, and a sixth laser diode 236A configured to emit a laser beam (e.g., a blue laser beam) 237A in a sixth direction D6. Notably, the additional camera 240B is configured to sense or detect fourth reflected light from the object W upon which the fourth laser light 233A contacts. The additional camera 240B is configured to sense or detect fifth reflected light from the pad 256 upon which the fifth laser light 235A contacts. The additional camera 240B is configured to sense or detect sixth reflected light from the object W upon which the sixth laser light 237A contacts. The processor is configured to determine an additional clearance height between the pad 256 and the object W using information from the fourth reflected light, the fifth reflected light, and the sixth reflected light, in the same manner as discussed herein with respect to the determination of the clearance height between the pad 258 and the object W.

### Initial Experiments

### Silicon Wafer

The following experiment was conducted with a silicon wafer, a simple green laser used for presentations, and the 2.5× camera lens from an Apple Iphone® 12 Pro Max (2778 ×1284 pixels 2.8K Full HD+) with the following characteristics: 12 MP 1/3.4″ sensor, 65 mm-equivalent f/2.2-aperture lens, phase detection autofocus (PDAF), optical image stabilization (OIS).

The phone and laser were positioned roughly 250 mm away from the point of interest.

### Wafer Surface

The following threshold was utilized to identify the green laser beam contacting the wafer surface. Note that the images taken are shown in FIGS. 15A-15D and are inverted.

binaryImage=greenChannel>=150& redChannel<100;

FIG. 15A shows the original image. FIG. 15B shows the image with green color converted to white and remaining color converted to black. FIG. 15C shows an enlarged view of the points of interest in FIG. 15B. FIG. 15D shows an enlarged view of the points of interest in FIG. 15A with the green color pixelated for analysis to determine whether the points of interest correspond to primary diffuse reflection, secondary diffuse reflection, or tertiary diffuse reflection, whether they correspond to the object (e.g., wafer) or the pad(s) of the end effector, and what the closets points are for determination of clearance.

The line in the bottom left in each image in FIGS. 15A-15D and labeled as point of interest \textcircled{1} in FIG. 15C is the laser contacting the wafer and some light diffusing back to the camera. The circular portion on the top right in each image in FIGS. 15A-15D and labeled as point of interest \textcircled{2} in FIG. 15C is the laser reflecting off of the wafer, hitting the desk, and diffusing back to the camera. The circular portion on the bottom right in each image in FIGS. 15A-15D and labeled as point of interest 3 in FIG. 15C is the image from the desk reflecting on the wafer and back to the camera.

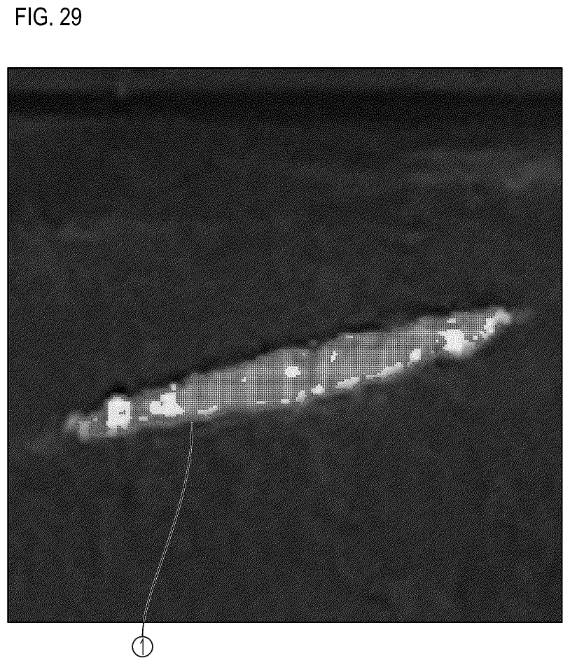

FIG. 29 shows an enlarged view of the line in the bottom left portion of FIG. 15D (relating to point of interest @ in FIG. 15C) that is the laser contacting the wafer and some light diffusing back to the camera.

### Simulation

We simulate the geometry of the proposed process to help prove out the concept.

### Body Representation

We represent a given surface by a 3×n dimensional vector where n are the number of points comprising the surface in three dimensional space.

$$W = {[ \begin{matrix}x & y & z\end{matrix} ]}^{T}$$

We can represent multiple surfaces which comprise a given body. For example, a wafer will have a top surface, a bottom surface, and surface around its perimeter: WT, WB, and W_{S}, respectively.

### Wafer Warpage

We can model the warpage of the wafer with the following model.

$$z = A * {x}^{2} - B * {y}^{2} + {h}_{wafer} / 2$$

### Translation and Rotation

These surfaces can be translated and rotated within the 3D environment.

$${}^{B} W {=}^{B} {P}_{A} + {}_{A}^{B} R * {W}_{A}$$

### Beam

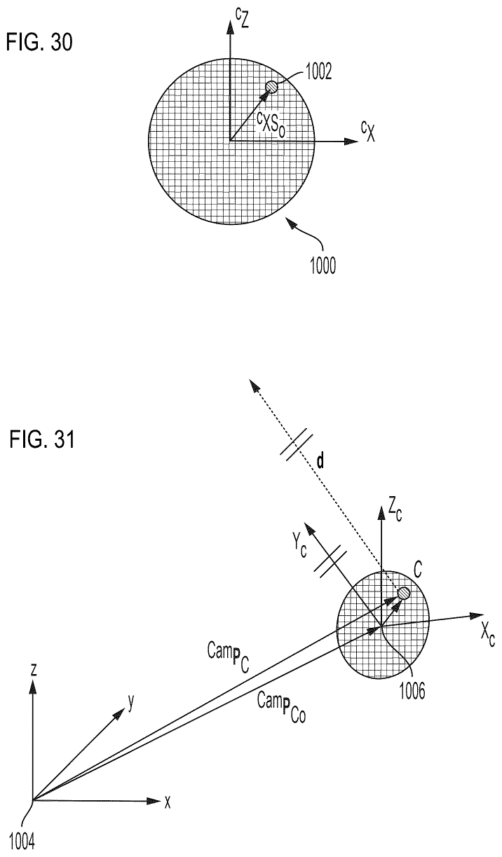

As shown in FIG. 30, the full light beam 1000 can be modeled as a series of individual, parallel rays (see, e.g., individual ray 1002) emanating orthogonally from a circle of a given diameter.

The origin of each ray within the beam can be individually defined in the beam coordinate frame by the vector ^{C}XS_{O}.

As shown in FIG. 31, using a camera origin 1004 and a beam origin 1006, the beam can have an origin and orientation within the inertial coordinate frame that can be represented by the following,

$${}^{Cam} {P}_{C} = {}^{Cam} {P}_{Co} + {R}_{beam} * {}^{C} {XS}_{o}$$

The direction of an individual ray within the beam coordinate frame can be represented by the unit vector,

$$d = {R}_{beam} * [ 0 ; 1 ; 0 ]$$

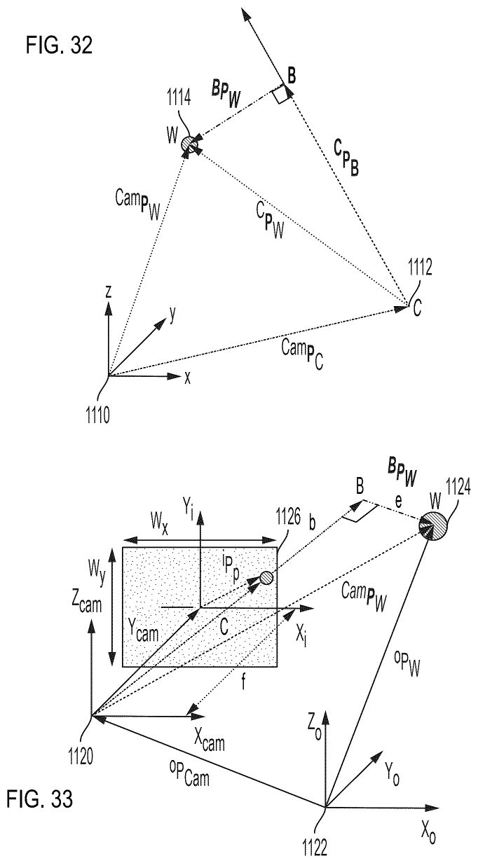

As shown in FIG. 32, using a camera origin 1110, a beam origin 1112, and an object element 1114, the vector defining the position of a given object element with respect to the beam is found through the equation,

$${}^{C} {P}_{W} = {}^{Cam} {P}_{W} - {}^{Cam} {P}_{C}$$

The scalar projection of ^{C}P_{W} onto the beam is found through the dot product

$$b = {}^{C} {{P}_{W}}^{T} * d$$

The beam vector to the element in the beam coordinate frame is the following,

$${}^{C} {P}_{B} = b * d$$

$${}^{C} {P}_{B} = {}^{C} {{P}_{W}}^{T} * d$$

The beam vector to the element in the camera coordinate frame is the following,

$${}^{Cam} {P}_{B} = {}^{Cam} {P}_{C} + {}^{Cam} {P}_{B}$$

The vector defining the orthogonal distance of the given element from the beam is the following,

$${}^{B} {P}_{W} = {}^{Cam} {P}_{W} - {}^{Cam} {P}_{B}$$

The scalar orthogonal distance is simply the norm of the vector,

$$e = \vert {}^{B} {P}_{W} \vert$$

We assume that a given beam will only strike one element of one surface in an environment of opaque objects. For each ray, we search all elements of all bodies. The element with the shortest associated beam length b that also has an e smaller than a defined threshold will be the element associated with that ray.

### Camera Imaging-Pixel Specific Capture

As shown in FIG. 33, using a camera origin/focal point 1120, an inertia coordinate frame 1122, an object element 1124, and a camera array 1126, we have placed the camera coordinate frame at the focal point of the camera. The camera has a lens that focuses all light within its field of view at the focal point. The camera will have a sensor array that captures the light some distance away from the focal point, the focal length, f.

Each element in the camera array will be associated with a pixel whose position is defined within the i coordinate frame by the vector, ⁱPₚ. The path of the ray of light that intends to find the focal point but is caught by the array is defined by the unit vector c and may be found in the following,

$${}^{Cam} {P}_{p} = [ 0 ; f ; 0 ] + {}^{i} {P}_{p}$$

We can determine the unit vector associated with the pixel vector,

$$c = {}^{Cam} {P}_{p} / \vert {}^{Cam} {P}_{p} \vert$$

We can find the position of a given element in the camera coordinate frame,

$${}^{Cam} {P}_{W} = {°P}_{W} - {°P}_{Cam}$$

The scalar projection of ^{Cam}P_{W} onto the camera light ray is found through the dot product

$$b = {}^{Cam} {{P}_{W}}^{T} * c$$

The beam vector to the element in the beam coordinate frame is the following,

$${}^{Cam} {P}_{B} = b * c$$

$${}^{Cam} {P}_{B} = {}^{Cam} {{P}_{W}}^{T} * c * c$$

The beam vector to the element in the camera coordinate frame is the following,

$${}^{Cam} {P}_{B} = {}^{Cam} {P}_{C} + {}^{C} {P}_{B}$$

The vector defining the orthogonal distance of the given element from the beam is the following,

$${}^{B} {P}_{W} = {}^{Cam} {P}_{W} - {}^{Cam} {P}_{B}$$

### Camera Imaging—General Capture

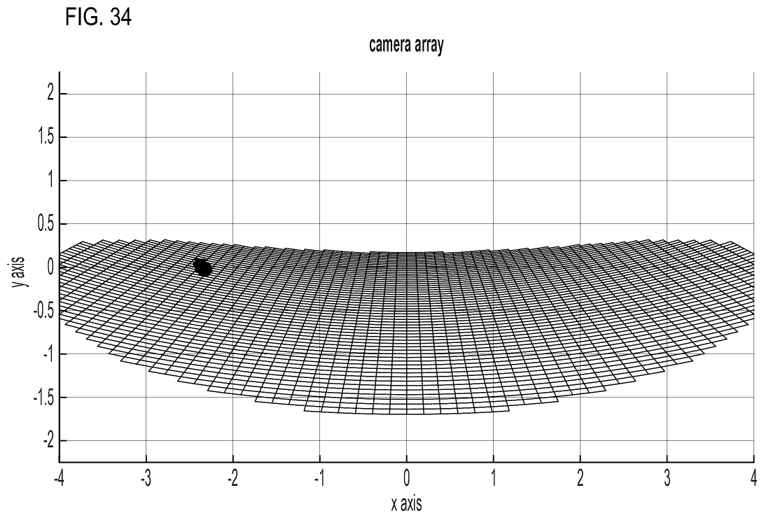

In the above, we found the specific beam of laser light that each camera pixel will see, which was done for the purpose of image processing simulation, and the results of which are shown in FIG. 34. However, we also like to see how a given body would be projected onto the camera array without having to identify the associated pixel.

The above disclosure provides a method that includes providing a first laser diode and a camera on an end effector; using the first laser diode to emit a first laser light in a first direction; using the camera to sense or detect first reflected light from an object upon which the first laser light contacts; and using a processor to determine a clearance height between the end effector and the object using information from the first reflected light.

In addition, the above disclosure provides a processor that can determine an amplitude of vibration of the end effector in a direction of the clearance height using the information from the first reflected light over a period of time.

The above disclosure further provides a method that includes providing a first laser diode and a camera on an end effector; using the first laser diode to emit a first laser light in a first direction; using the camera to sense or detect first reflected light from an object upon which the first laser light contacts; and using a processor to determine an amplitude of vibration of the end effector in a direction extending between the end effector and the object using information from the first reflected light over a period of time.

It should be noted that the exemplary embodiments depicted and described herein set forth the preferred embodiments of the present invention, and are not meant to limit the scope of the claims hereto in any way. Numerous modifications and variations of the present invention are possible in light of the above teachings. It is therefore to be understood that, within the scope of the appended claims, the invention may be practiced otherwise than as specifically described herein.

What is claimed is:

1. A robot end effector comprising:
a first laser diode configured to emit a first laser light in a first direction;
a camera configured to sense or detect first reflected light from an object upon which the first laser light contacts; and
a processor configured to determine a clearance height between the end effector and the object using information from the first reflected light.

2. A robot comprising:
a robot arm having the robot end effector according to claim 1,
wherein the first laser diode is provided on the robot end effector.

3. The robot according to claim 2, further comprising:
a first pad provided on an upper surface of the robot end effector, the first pad being configured to receive a wafer thereon when the wafer is supported by the robot end effector; and
a second laser diode provided on the robot end effector, the second laser diode being configured to emit a second laser light in a second direction,
wherein the camera is configured to sense or detect second reflected light from the first pad upon which the second laser light contacts, and
wherein the processor is configured to determine the clearance height between the first pad of the robot end effector and the object using information from the first reflected light and the second reflected light.

4. The robot according to claim 3,
wherein the first direction is parallel to the second direction.

5. The robot according to claim 3,
wherein the first laser light is within a first wavelength range,
wherein the second laser light is within a second wavelength range, and
wherein the first wavelength range is different from the second wavelength range.

6. The robot according to claim 3, further comprising:
a third laser diode provided on the end effector, the third laser diode being configured to emit a third laser light in a third direction,
wherein the camera is configured to sense or detect third reflected light from the object upon which the third laser light contacts, and
wherein the processor is configured to determine the clearance height between the first pad of the end effector and the object using information from the first reflected light, the second reflected light, and the third reflected light.

7. The robot according to claim 6,
wherein the first direction is provided at a non-zero angle with respect to the third direction when viewed in plan view, and
wherein the first direction is parallel to the second direction.

8. The robot according to claim 6,
wherein the first laser light is within a first wavelength range,
wherein the second laser light is within a second wavelength range,
wherein the third laser light is within a third wavelength range, and
wherein the first wavelength range, the second wavelength range, and the third wavelength range are each different.

9. The robot according to claim 6,
wherein the first direction intersects the first pad when viewed in plan view, and
wherein the third direction intersects the first pad when viewed in plan view.

10. The robot according to claim 2,
wherein the processor determines the clearance height by using a predetermined closest point of the end effector to the object in a height direction and by determining a closest point of the object to the end effector in the height direction using information from the first reflected light.

11. The robot according to claim 3,
wherein the processor determines the clearance height by determining a closest point of the first pad to the object in a height direction and by determining a closest point of the object to the first pad in the height direction using information from the first reflected light and the second reflected light.

12. The robot according to claim 3,
wherein the processor determines the clearance height by analyzing first pixels of an image from the camera relating to the first reflected light and second pixels of the image from the camera relating to the second reflected light.

13. The robot according to claim 3,
wherein the first direction intersects the first pad when viewed in plan view.

14. The robot according to claim 3, further comprising:
a second pad provided on the upper surface of the end effector, the second pad being configured to receive the wafer thereon when the wafer is supported by the end effector;
a fourth laser diode provided on the end effector, the fourth laser diode being configured to emit a fourth laser light in a fourth direction;
a fifth laser diode provided on the end effector, the fifth laser diode being configured to emit a fifth laser light in a fifth direction; and
an additional camera configured to sense or detect fourth reflected light from the object upon which the fourth laser light contacts;
wherein the additional camera is configured to sense or detect fifth reflected light from the second pad upon which the fifth laser light contacts, and
wherein the processor is configured to determine an additional clearance height between the second pad and the object using information from the fourth reflected light and the fifth reflected light.

15. The robot according to claim 6, further comprising:
a second pad provided on the upper surface of the end effector, the second pad being configured to receive the wafer thereon when the wafer is supported by the end effector;
a fourth laser diode provided on the end effector, the fourth laser diode being configured to emit a fourth laser light in a fourth direction;
a fifth laser diode provided on the end effector, the fifth laser diode being configured to emit a fifth laser light in a fifth direction;
a sixth laser diode provided on the end effector, the sixth laser diode being configured to emit a sixth laser light in a sixth direction; and
an additional camera configured to sense or detect fourth reflected light from the object upon which the fourth laser light contacts,
wherein the additional camera is configured to sense or detect fifth reflected light from the second pad upon which the fifth laser light contacts,
wherein the additional camera configured to sense or detect sixth reflected light from the object upon which the sixth laser light contacts, and
wherein the processor is configured to determine an additional clearance height between the second pad and the object using information from the fourth reflected light, the fifth reflected light, and the sixth reflected light.

16. The robot according to claim 3, further comprising:
a second pad provided on the upper surface of the end effector, the second pad being configured to receive the wafer thereon when the wafer is supported by the end effector;
a fourth laser diode provided on the end effector, the fourth laser diode being configured to emit a fourth laser light in a fourth direction; and
a fifth laser diode provided on the end effector, the fifth laser diode being configured to emit a fifth laser light in a fifth direction,
wherein the camera is configured to sense or detect fourth reflected light from the object upon which the fourth laser light contacts,
wherein the camera is configured to sense or detect fifth reflected light from the second pad upon which the fifth laser light contacts, and
wherein the processor is configured to determine an additional clearance height between the second pad and the object using information from the fourth reflected light and the fifth reflected light.

17. The robot according to claim 6, further comprising:
a second pad provided on the upper surface of the end effector, the second pad being configured to receive the wafer thereon when the wafer is supported by the end effector;
a fourth laser diode provided on the end effector, the fourth laser diode being configured to emit a fourth laser light in a fourth direction;
a fifth laser diode provided on the end effector, the fifth laser diode being configured to emit a fifth laser light in a fifth direction; and
a sixth laser diode provided on the end effector, the sixth laser diode being configured to emit a sixth laser light in a sixth direction,
wherein the camera is configured to sense or detect fourth reflected light from the object upon which the fourth laser light contacts,
wherein the camera is configured to sense or detect fifth reflected light from the second pad upon which the fifth laser light contacts,
wherein the camera is configured to sense or detect sixth reflected light from the object upon which the sixth laser light contacts, and
wherein the processor is configured to determine an additional clearance height between the second pad of the end effector and the object using information from the fourth reflected light, the fifth reflected light, and the sixth reflected light.

18. The robot according to claim 3,
wherein the first laser diode and the second laser diode are both orthogonal to the clearance height.

19. A method comprising:
providing a first laser diode and a camera on an end effector;
using the first laser diode to emit a first laser light in a first direction;
using the camera to sense or detect first reflected light from an object upon which the first laser light contacts; and
using a processor to determine a clearance height between the end effector and the object using information from the first reflected light.

20. The method according to claim 21,
wherein the processor determines an amplitude of vibration of the end effector in a direction of the clearance height using the information from the first reflected light over a period of time.

21. A method comprising:
providing a first laser diode and a camera on an end effector;
using the first laser diode to emit a first laser light in a first direction;
using the camera to sense or detect first reflected light from an object upon which the first laser light contacts; and
using a processor to determine an amplitude of vibration of the end effector in a direction extending between the end effector and the object using information from the first reflected light over a period of time.
